(19) United States
(12) Patent Application Publication
(10) Pub. No.: US 2010/0104771 A1
(43) Pub. Date: Apr. 29, 2010

(54) ELECTRODE AND POWER COUPLING SCHEME FOR UNIFORM PROCESS IN A LARGE-AREA PECVD CHAMBER

(75) Inventors: Jozef Kudela, Sunnyvale, CA (US); Tsutomu (Tom) Tanaka, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/493,721

(22) Filed: Jun. 29, 2009

Related U.S. Application Data
(60) Provisional application No. 61/108,365, filed on Oct. 24, 2008.

(51) Int. Cl. C23C 16/50; C23C 16/00; H05H 1/24

(52) U.S. Cl. 427/569; 118/723 E

(57) ABSTRACT

Embodiments discussed herein generally include electrodes having parallel ferrite boundaries that suppress RF currents perpendicular to the ferrite boundary and absorb magnetic field components parallel to the boundary. The ferrites cause the standing wave to stretch outside the ferrites and shrink inside the ferrite. Thus, the RF current on the uncovered electrode area will be a plane wave, quasi-uniform (in a direction perpendicular to the ferrites) propagating in the direction parallel to the ferrites.

### CROSS-REFERENCE TO RELATED APPLICATIONS

This application claims priority to U.S. Provisional Patent Application Ser. No. 61/108,365 (APPM/013758L), filed Oct. 24, 2008, which is herein incorporated by reference.

### BACKGROUND OF THE INVENTION

1. Field of the Invention

Embodiments of the present invention generally relate to a plasma enhanced chemical vapor deposition (PECVD) apparatus.

2. Description of the Related Art

As demands for larger flat panel displays (FPDs) and solar panels for consumers (and consequently, demands for higher manufacturing cost-efficiency from the FPD and solar panel manufacturers), continues to increase, the size of PECVD chambers that are used for depositing thin films used for FPDs and solar panels increases. The chambers used in the deposition process are typically capacitively driven parallel-plate reactors using RF or VHF fields to ionize and dissociate processing gas between the plate electrodes. Due to reactor dimensions and boundary conditions on the electrodes, the excited fields inherently form standing waves, which may cause non-uniformities in plasma and deposited films.

The standing waves and plasma non-uniformities have a strong influence on the thickness and properties of thin films deposited by PECVD reactors or on the process uniformity in plasma processing chambers in general. Non-uniform films may lead to the so-called “mura effects” on FPDs or to low-efficient cells in solar panels. In some cases, plasma non-uniformity may lead to non-functioning devices.

Therefore, there is a need for a capacitively driven parallel plate reactor designed to increase plasma uniformity and overcome standing wave effects.

### SUMMARY OF THE INVENTION

Embodiments discussed herein generally include electrodes having parallel ferrite boundaries that suppress RF currents perpendicular to the ferrite boundary and absorb magnetic field components parallel to the boundary. The ferrites cause the standing wave to stretch outside the ferrites and shrink inside the ferrite. Thus, the RF current on the uncovered electrode area will be a plane wave, quasi-uniform (in a direction perpendicular to the ferrites) propagating in the direction parallel to the ferrites.

In one embodiment, an apparatus is disclosed. The apparatus includes a chamber body having a slit valve opening through a first wall of the chamber body and a gas distribution showerhead disposed in the chamber body above the slit valve opening. The apparatus may also include a backing plate coupled to the chamber body and spaced form the gas distribution showerhead. The backing plate may have a substantially rectangular shape. A first side of the backing plate faces the gas distribution showerhead. The backing plate has a second side opposite the first side. The apparatus also may have a power source coupled to the backing plate at one or more locations and one or more first ferrite pieces extending along the second side of the backing plate.

In another embodiment, an apparatus may include a substantially rectangular shaped gas distribution showerhead, a backing plate coupled to the gas distribution showerhead, and one or more first ferrite blocks resting on the backing plate.

In another embodiment, a method may include applying an RF current to a backing plate of an apparatus. The apparatus may have a gas distribution showerhead coupled to the backing plate and one or more ferrite blocks resting on an edge of the backing plate. The RF current may be applied such that at least a portion of the RF current is suppressed in a direction perpendicular to the ferrite material. The method may also include introducing a processing gas through the gas distribution showerhead, igniting the processing gas into a plasma, and depositing material onto the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic cross sectional view of a PECVD apparatus according to one embodiment.

FIG. 1B is a schematic cross sectional view of the PECVD apparatus of FIG. 1A having ferrites 132 disposed therein.

FIG. 1C is a schematic isometric view of the backing plate of FIG. 1B.

FIG. 1D is a schematic top view of an electrode having a single, substantially centered, RF feed location.

FIG. 1E is a schematic bottom view of the electrode of FIG. 1D.

FIG. 2A is a schematic isometric top view of an electrode having a single, substantially centered RF feed location according to one embodiment.

FIG. 2B is a graph showing the effects of a ferrite boundary on the standing wave profile.

FIG. 2C is a schematic isometric view of the standing wave effect in the absence of ferrite boundaries.

FIG. 2D is a schematic isometric view of the standing wave effect in the presence of ferrite boundaries.

FIG. 3A shows a normalized electrode voltage distribution for a center fed RF feed.

FIG. 3B shows a normalized electrode voltage distribution for an RF feed displaced 0.5 meters from center.

FIG. 4 is a schematic cross sectional view showing various locations for ferrites in a parallel plate apparatus.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments discussed herein generally include the use of one or more ferrite elements that are positioned within a plasma processing chamber to redistribute and/or shape a generated plasma formed in a processing area within the processing chamber. By positioning and orienting the ferrite elements in relation to the RF driven electrode, the RF feed position on the RF driven electrode, and/or features in the processing chamber the uniformity of the generated plasma can be altered to provide an improved plasma processing result. The ferrite elements may also be used to alter the RF standing wave patterns and generated field lines in various directions within the plasma processing chamber. In general, RF currents that are formed in a direction perpendicular to the boundary of the ferrite element are suppressed due to the preferential flow of the generated magnetic field through the ferrite element rather than through free-space, and the RF currents in a direction parallel to the ferrite boundary will be enhanced. While the term “ferrite element” and “ferrite material” are used herein, these terms are not intended to be limiting as to scope of invention described herein. In general, the ferrite elements can be formed from any material that can be used to provide a path through which the generated fields (e.g., magnetic fields), created by the flow of RF current within portions of the plasma processing chamber, will preferentially flow. In one example, the ferrite elements are formed from a ferromagnetic material.

Embodiments disclosed herein will be discussed with reference to a PECVD apparatus available from AKT America, Inc., a subsidiary of Applied Materials, Inc., Santa Clara, Calif. It is to be understood that the embodiments may be practiced on apparatus sold by other manufacturers.

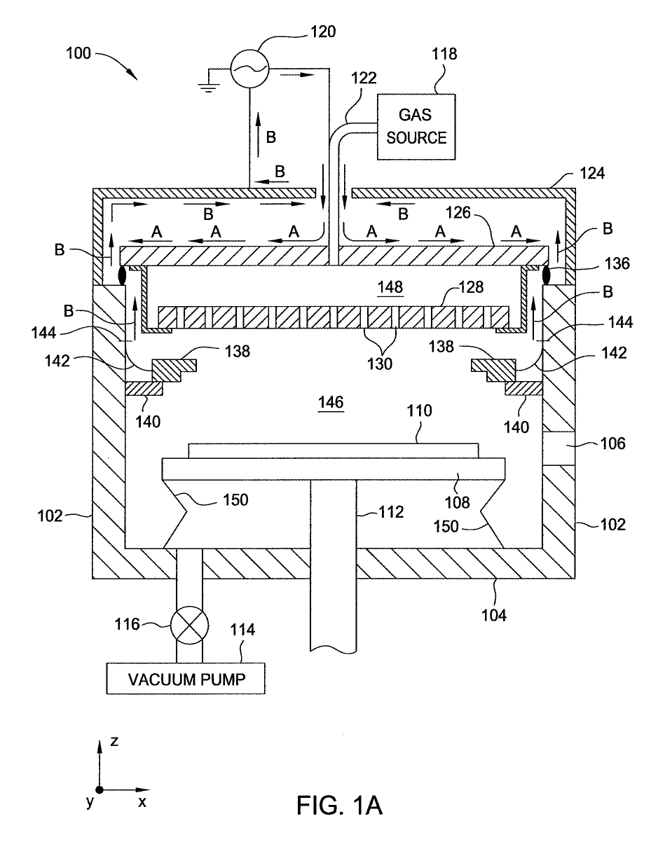

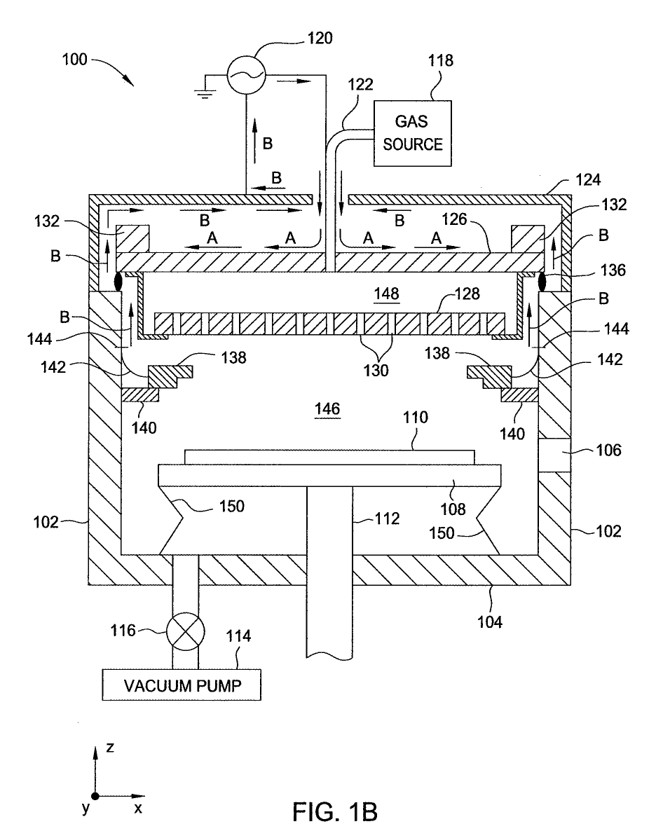

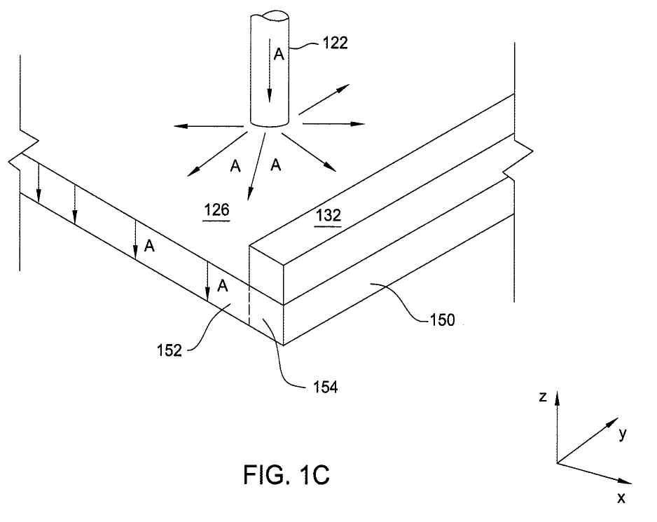

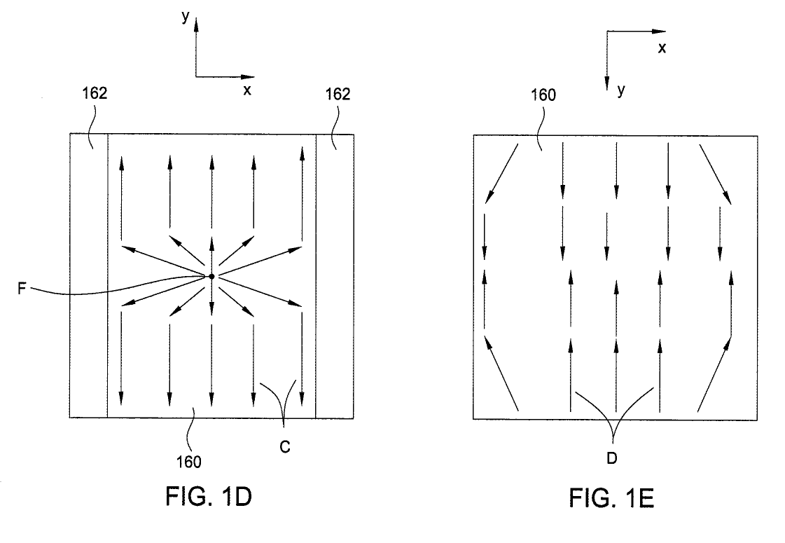

FIG. 1A is a schematic cross sectional view of a plasma processing chamber, or PECVD apparatus 100, according to one embodiment. The apparatus 100 comprises a plurality of walls 102 and a bottom 104. In one embodiment, the walls 102 and the bottom 104 may comprise a conductive material, such as aluminum. Through one or more walls 102, a slit valve opening 106 may be present. The slit valve opening 106 permits a substrate 110 to enter and exit the apparatus 100.

The substrate 110 may be placed on a susceptor 108 when in the apparatus 100. The susceptor 108 may be raised and lowered on a shaft 112. In one embodiment, the shaft 112 and the susceptor 108 may comprise a conductive material, such as aluminum. The apparatus 100 may be evacuated by a vacuum pump 114. A valve 116 may be coupled between the chamber and the vacuum pump 114 to adjust the vacuum level of the apparatus 100.

Processing gas may be introduced into the apparatus 100 from a gas source 118 through a tube 122 that passes through the chamber lid 124. The tube 122 is coupled to the backing plate 126 to permit the processing gas to pass through the backing plate 126 and enter a plenum 148 between the backing plate 126 and the gas distribution showerhead 128. In one embodiment, the tube 122, the backing plate 126, and the gas distribution showerhead 128 may comprise a conductive material. In another embodiment, the tube 122, backing plate 126, and gas distribution showerhead 128 may comprise aluminum. The processing gas spreads out in the plenum 148 and then passes through gas passages 130 formed through the gas distribution showerhead 128 to the processing area 146.

A power source 120 is also coupled to the tube 122. In one embodiment, the power source 120 comprises an RF power source capable of generating RF currents at a frequency of about 13.56 MHz. In another embodiment, the RF power source 120 comprises a VHF power source capable of generating VHF currents, such as about 40 MHz or about 60 MHz. Depending upon the size of the RF power source, the frequency applied may be between about 0.4 MHz and about a few hundred MHz. In general, the power may be applied such that ⅛^{th} of the free space wavelength in vacuum at the applied frequency is comparable to the chamber diagonal. The chamber diagonal is the distance across a rectangular chamber from one corner to another corner diagonally opposite.

The current from the power source 120 flows along the outside surface of the tube 122 to the backing plate 126. RF current has a ‘skin effect’ in that the current does not penetrate all the way through a conductive body such as the tube 122 and the backing plate 126. RF current travels along the outside surface of a conductive object. The RF current then travels down a suspension 134 to the front face of the gas distribution showerhead 128. In one embodiment, the suspension 134 may comprise a conductive material, such as aluminum. The RF current flows along a path shown by arrows “A”. Thus, the RF current travels along the back surface of the backing plate 126, the side surface of the backing plate 126 the outside surface of the suspension 134, and the bottom surface of the gas distribution showerhead 128.

In the embodiment shown in FIG. 1A, the gas tube 122 is fed into the substantial center of the backing plate 126. Hence, the RF current supplied to the gas tube 122 is also fed to the backing plate 126 at the substantial center thereof. It is to be understood that, the RF current coupling location, could be moved to suit the needs of the user. For example, the RF current coupling location may be moved to compensate for the RF current return or for chamber asymmetry.

The RF current travels along an RF path from the source driving it and returning to the source driving it. The RF current flows down the outside of the gas tube 122 to the upper surface of the backing plate 126. The RF current then travels along the upper surface of the backing plate 126 and down the side of the backing plate 126 to the suspension 134 that couples the backing plate 126 to the gas distribution showerhead 128. From the suspension 134, the RF current then travels to the gas distribution showerhead 128 and along the surface of the gas distribution showerhead 128 that faces the substrate 110. The RF current then couples through the plasma that is generated during processing to the susceptor 108. The RF current then travels along the susceptor 108. The RF current seeks to return to the source driving it and therefore will seek the shortest path. In some cases, the RF current will flow along the shadow frame 138 (if the shadow frame is conductive) when it touches the susceptor 108 and the straps 142 coupling the shadow frame 138 to the walls 102 of the chamber. In other cases, the RF current travels down along the susceptor 108 to straps 150 that couple the susceptor 108 to the chamber bottom 104. The straps 150 shorten the RF return path because the RF current does not need to travel along the bottom of the susceptor 108 and down the shaft 112 to then begin a return along the bottom 104 of the chamber. The RF current flows along the walls 102 of the chamber and then the lid 124 and back to the power source 120. The longer the RF return path, the greater the likelihood of arcing or parasitic plasma igniting within the chamber in undesired locations. Arcing and parasitic plasma may sap energy from the deposition plasma and thus lead to non-uniform deposition conditions.

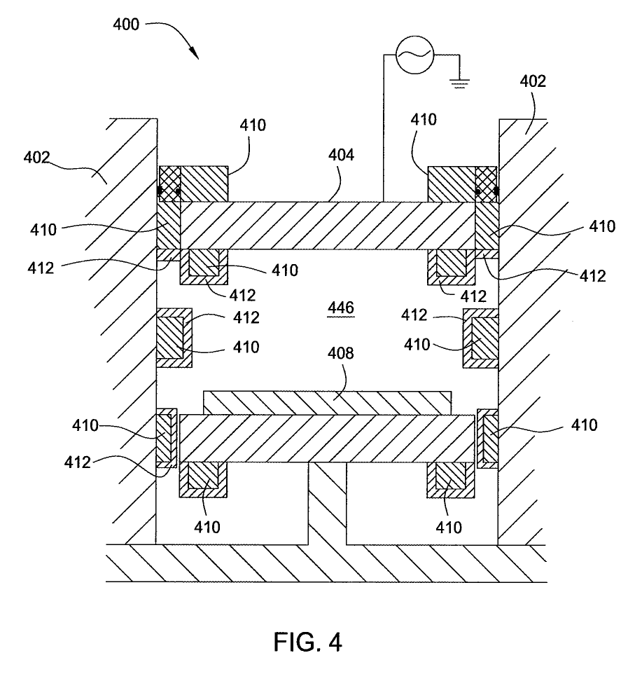

In the embodiment shown in FIG. 1B, ferrite 132 boundaries on the top of the backing plate 126 are present. FIG. 1C is a close-up isometric view of the right edge of the backing plate 126 and ferrite 132 shown in FIG. 1B. In one embodiment, as shown in FIG. 1C, the ferrites 132 are generally bar shaped and aligned along a side 150 of the backing plate 126 that is parallel to the y-direction. It is to be understood that the ferrites 132 are not limited to bar shaped structures. For example, the ferrites 132 may be round shaped rods that span the length of the backing plate 126. Additionally, the ferrites 132 may comprise multiple pieces spaced apart where the spacing is less than the width of the ferrite 132. As will be discussed below in regards to FIG. 4, the ferrites 132 also need not be at the edge of the backing plate 126 or directly in contact with the backing plate 126. The ferrites 132 can be proximate to the backing plate 132. The ferrite's 132 relative permeability, orientation and geometry will shape the fields created by the delivery of RF current to the backing plate 126 and gas distribution showerhead 128. By orienting the ferrites 132 the generated standing waves in the processing area 146 of the PECVD apparatus 100 will be altered. Referring to FIGS. 1B and 1C, generated plane waves propagated in the y-direction will generally be quasi-uniform in the x-direction due to the preferential flow of the induced magnetic fields within the ferrites material aligned along the y-direction, while the waves propagating in the y-direction will be relatively unaffected by the bar shaped ferrites 132. Thus, the variation in fields will decrease in the x-direction between the two ferrites 132.

In one embodiment, the non-uniformity in the waves propagating in the y-direction is resolved by altering the standing wave pattern by controlling the phase delivered to two or more RF feeds that are spaced apart in the y-direction or by moving the substrate in the y-direction. Further control and/or improvement of the uniformity may be achieved by using multiple feeds with uneven power distribution and/or using multiple ferrite 132 boundaries on the backing plate 126. The design and power coupling may enhance the plasma uniformity in a direction parallel to the long axis of the ferrite's 132 (e.g., y-direction). Therefore, any plasma uniformity issues created by the asymmetric shape of the PECVD apparatus 100, such as near the slit valve opening 106 may be alleviated by placing ferrites 132 parallel to the slit valve opening 106. In one embodiment, the ferrites 132 may be oriented perpendicular to the slit valve opening 106.

The standing wave effects and related plasma non-uniformities may be overcome to an extent by using shaped electrodes, lens electrodes, cavities behind resistive electrodes, multiple RF feeds or generators, multiple ports with phase modulation, lower frequencies, tuning the processing parameters such as chamber pressure, and combinations thereof in addition to the positioning and alignment of one or more ferrites 132.

For the embodiment shown in FIG. 1B, the ferrites 132 extend along an edge of the backing plate 126 parallel to the slit valve opening 106. In one embodiment, the ferrites 132 may extend along an edge of the backing plate 126 perpendicular to the slit valve opening 106. The edges of the backing plate 126 extending perpendicular to the slit valve opening 106 do not have ferrites 132 extending thereon. The ends of the ferrites 132 do cover a short distance of the edge perpendicular to the slit valve opening 106, but its effect should be minimal. However, in some configurations it may be desirable to shape or align the ferrites 132 in other orientations. For example, bar shaped ferrites 132 may extend along the edge of the backing plate 126 perpendicular to the slit valve opening 106 instead of the edges parallel to the slit valve opening 106. Additionally, if desired, the ferrites 132 may be present on other edges. However, if ferrites 132 are present on other edges, it may be necessary to have some gaps therebetween to permit the RF current to travel down to the gas distribution showerhead 128. In other embodiments, the ferrites 132 may be configured in a circular, arc, or other desired shape to further reduce non-uniformities in the plasma formed in the processing area 146. The ferrites 132 are used to permit the applied current to follow a predetermined path such that the plasma is substantially uniform in a predetermined direction.

FIG. 1C is a schematic isometric view of the backing plate 126 of FIG. 1B that shows the RF current suppressed from passing along the backing plate 126 where the ferrites 132 are situated such that little or no RF current passes along the side 150 parallel to the ferrite 132. On the other hand, on the side 152 perpendicular to the bar shaped ferrite 132, the RF current may pass freely down the side 152. The ferrite 132 may, however, reduce or prevent the RF current from traveling down the side 142 in the area 154 directly underneath the ferrite 132.

It is to be understood that while the ferrites 132 have been shown as a single piece spanning the entire length of the backing plate 126, the ferrites 132 may comprise multiple pieces. The multiple pieces may each span the entire length or the multiple pieces may be coupled together to collectively span the entire length. Additionally, if desired, a ferrite 132 may be formed from multiple ferrite pieces that are spaced a distance apart. The ferrites 132 may be either parallel or perpendicular to the slit valve opening 106. Additionally, the ferrites 132 may be proximate to the backing plate 126. In one embodiment, the ferrites 132 may be in contact with the backing plate 126. The ferrites 132 may be cooled.

In the apparatus 100, there are four walls 102. Of those four walls 102, three of the walls 102 are substantially identical and look substantially identical to the RF current (in absence of the ferrites) when it travels thereon returning to the power source 120 as shown by arrows “B”. The fourth wall 102, however, is different than the other walls 102 and looks different to the RF current as it returns to the power source 120. The fourth wall 102 has the slit valve opening 106 formed therethrough. The RF current travels a circuitous path along the wall 102 having the slit valve opening 106. The RF current actually travels around the slit valve opening 106. Thus, the RF current traveling along the wall 102 having the slit valve opening 106 has a longer inductive path to return to the power source 120 as compared to the three other walls 102.

The longer the path the RF current has to travel to return to the RF power source 120 the larger the ohmic losses. Hence, the potential difference between the RF current flowing within the three substantially identical walls 102 back to the power source 120 is different than the RF current flowing within the wall 102 having the slit valve opening 106. The slit valve opening 106 may also cause a plasma to be formed therein, thus causing the generated plasma to be unevenly distributed in processing area 146. With an uneven plasma distribution, a non-uniform deposition of material onto the substrate 110 may occur.

The ferrites 132 may be used to counteract the effect of the slit valve opening 106. In the embodiment shown in FIG. 1B, the ferrite 132 extends parallel to the slit valve opening 106. The ferrites 132 suppress the RF current flowing along the edge of the backing plate 126 having ferrites 132 thereon and hence, the side of the gas distribution showerhead 128. The RF current, when returning to the source 120, seeks to take the shortest path possible. Hence, when returning to the source 120, the RF current will flow along the walls 102 perpendicular to the slit valve opening 106 (and hence, the ferrites 132) because the walls 102 perpendicular to the slit valve opening 106 (z-direction in FIG. 1A-1C) (and hence, the ferrites 132) offer the shortest path to return to the source 120. Some RF current may, however, may return to the source 120 along the walls 102 parallel to the slit valve opening 106 (y-direction in FIG. 1A-1C) (and hence, the ferrites 132), but the amount of RF current that flows along the walls 102 parallel to the slit valve opening 106 (and hence, the ferrites 132) is insignificant relative to the RF current returning to the source 120 along the walls 102 perpendicular to the slit valve opening 106 (and hence, the ferrites 132). Therefore, because little or no RF current returns to the source 120 along the walls 102 parallel to the slit valve opening 106 (and hence, the ferrites 132), the negative effect of the slit valve opening 106 may be substantially reduced, or in some cases, eliminated. Thus, the amount of current traveling along the slit valve opening path 106 is small enough that the plasma is not pulled toward the slit valve opening 106. If the plasma is pulled towards the slit valve opening 106, then the plasma is not uniformly spread across the processing area 146.

When the susceptor 108 raises the substrate 110 for processing, the susceptor 108 encounters a shadow frame 138 while moving to the processing position. The shadow frame 138 may prevent unwanted deposition from occurring on the areas of the susceptor 108 that are not covered by the substrate 110. The shadow frame 138 may rest on a ledge 140 prior to being displaced by the susceptor 108. The shadow frame 138 may also be a part of the RF return path. One or more straps 142 may be coupled to both the shadow frame 138 as well as the inside surface of the walls 102. The straps 142 may be coupled to the inside surface of the walls 102 with one or more fastening mechanisms 144. In one embodiment, the fastening mechanism 144 may comprise a screw. The RF or VHF current travels along the bottom electrode, the straps 142, the inside surface of the walls 102, the lid 124, and back to the power source 120 as shown by arrows “B” to complete the RF circuit.

By suppressing RF current with the ferrites spanning a length of the backing plate 126 parallel to the slit valve opening 106, the RF current in the direction of the slit valve opening (and opposite thereto) is controlled. However, because no ferrites 132 are oriented and/or aligned perpendicular to the slit valve opening 106 (or vice versa), the RF current that runs parallel to the slit valve opening 106 (or vice versa) between the ferrite boundaries is not controlled. Thus, the ferrites 132 remove one degree of uncertainty to control of the RF current. The control of the RF current in the direction parallel to the slit valve opening 106 (y-direction) aids in plasma uniformity and thus, deposition uniformity.

Not wishing to be bound by theory unless specifically set forth in the claims, it is believed that the ferrites cause the standing wave to stretch outside the ferrites and thus shrinking its affect in the regions found between the ferrites 132. Thus, as noted above, the RF current on the uncovered electrode area will be a quasi-uniform plane wave in a direction perpendicular to the ferrites, but will propagate in the direction parallel to the ferrites. The single RF feed location induces the same fields/currents on the gas distribution showerhead 128 as if two “mirror feeds” had been induced to the bottom of the showerhead at the edges of the gas distribution showerhead 128. The mirror feeds would be spaced by two electrode widths (2w ), be same phased, and be prorated in amplitude. A standing wave would be formed on the gas distribution showerhead 128 with a maximum in the center. Thus, the single RF feed will induce a standing wave pattern that has a maximum in the center of the bottom surface of the gas distribution showerhead 128.

To deposit material on the substrate 110, processing gas is introduced from the gas source 118 through the backing plate 126 and into the plenum 148. Then, the processing gas passes through the gas passages 130 formed in the gas distribution showerhead 128 and into the processing area 146. The RF current flows along the tube 122, the back surface of the backing plate 126, the bracket 134, and the front surface of the showerhead 128. The RF fields then ignite the processing gas to form a plasma that causes the excited gas species found in the processing area 146 to deposit a desired material onto the substrate 110. Generally, the RF current propagates through the processing area 146 to the substrate 110 and along the shadow frame 138, the straps 142, the walls 102, and the lid 124 back to the power source 120. In one embodiment, the straps 142 may be present along the walls 102 perpendicular to the ferrites 132 but not present on the walls parallel to the ferrites 132. In another embodiment, the straps 142 may be coupled to all walls 102.

FIG. 1D is a schematic top view of an electrode 160 having a single, substantially centered, RF feed location “F”. FIG. 1E is a schematic bottom view of the electrode 160 of FIG. 1C. As seen in FIG. 1D, ferrites 162 span a length of a side of the electrode 160. The RF current is fed to the electrode at the substantial center thereof. The RF current travels out from the center in substantially all directions on the surface of the electrode 160 as shown by arrows “C”. The RF current does not travel through the ferrites 162. Thus, the RF current that does not flow to the ferrite 162 continues to flow along its path. Due to the presences of the ferrites 162, substantially no current flows down to the bottom of the electrode 160 along the walls parallel to the ferrites 162.

As shown in FIG. 1E, the RF current that flows on the bottom surface is affected by the ferrites 162. Due to the ferrites 162 suppressing RF current from traveling along the sidewalls parallel to the ferrites 162, substantially the only RF current that travels down to the bottom surface of the electrode 160 will travel to the bottom surface along sidewalls perpendicular to the ferrites 162. Thus, the RF current that travels along the bottom surface of the electrode 160 will flow substantially parallel to the ferrites 162.

While the term ferrite has been used in the present application, it is to be understood that any ferromagnetic material may be used including non-oriented, amorphous ferromagnetic material. Additionally, magnets may be used. The permeability of the ferrites may be predetermined to suit the needs of the user.

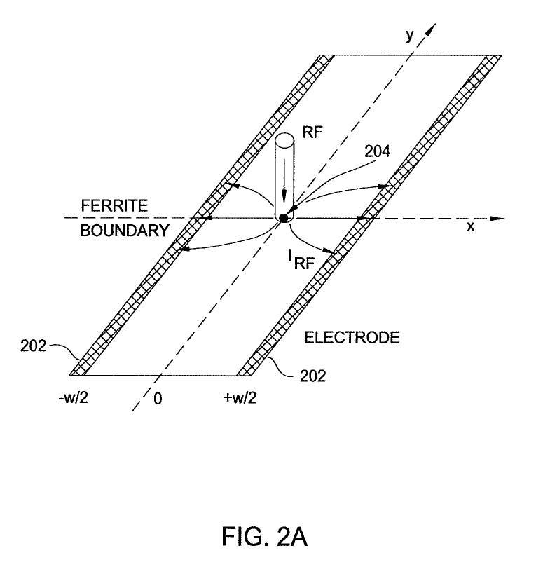

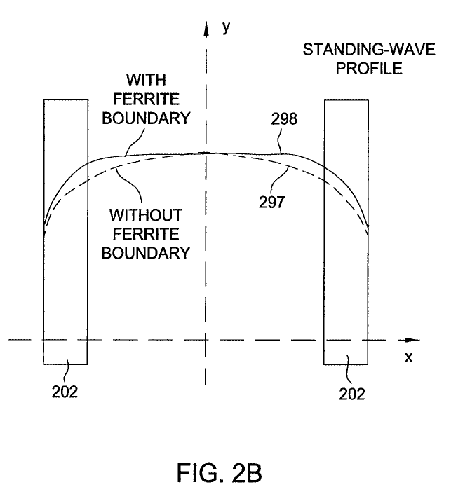

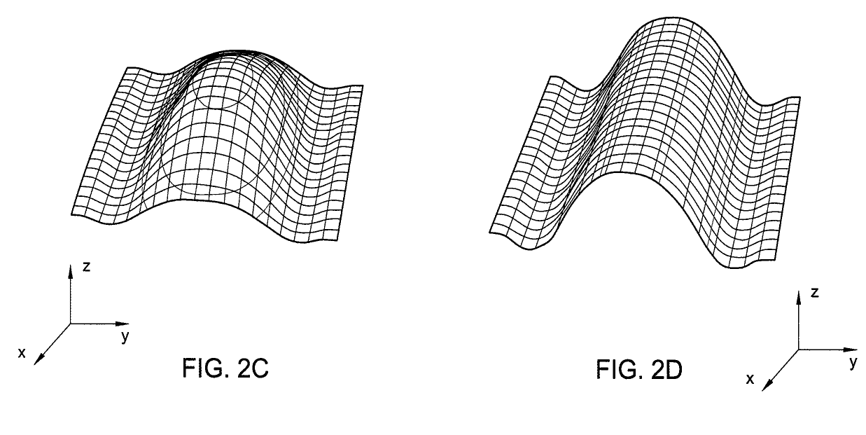

FIG. 2A is a schematic isometric top view of an electrode having a single, substantially centered RF feed location 204 according to one embodiment. FIG. 2B is a plot illustrating the effects of using symmetric ferrite boundaries on the standing wave profile formed in the x-direction, which is perpendicular to the elongated direction of the ferrites 202 (FIG. 2A). Lines 297 and 298 illustrate the profile of a standing wave plotted in the x-direction when no ferrite boundaries are present and when ferrite boundaries are present, respectively. FIG. 2A shows ferrite boundaries along two sides of the electrode. The ferrite boundaries on the electrode edges move part of the standing wave profile into the ferrites (i.e., the standing wave pattern on the uncovered electrode area will be spread and thus, more uniform) as shown in FIG. 2B which compares the standing wave profile for an electrode with ferrites to an electrode without ferrites. As shown in FIG. 2B, the standing wave profile in the situation where ferrites are present results in a flatter profile as compared to the situation where no ferrites are present. By flattening out the standing wave profile, the plasma uniformity in the x-direction may be substantially uniform. The RF currents may be enhanced in the direction parallel to the ferrite boundary and suppressed in the direction perpendicular to the ferrite boundary. A plane wave like propogation between the ferrite boundaries (i.e., magnetic field components parallel to the ferrite boundaries move into the ferrites) may be present.

As shown in FIG. 2B, when no ferrite boundary is present, the standing wave profile (i.e., line 297), has a peak or maximum in the substantial center along the Y axis. The standing wave profile then gradually decreases from the center. The center high maximum or peak produces a higher concentration of plasma near the center of the electrode (showerhead in PECVD). The center high maximum, when viewed isometrically, will have a dome shape such as shown in FIG. 2C. The RF current is flowing to the bottom surface of the electrode from all directions and thus, confluences at the center to create the dome shape shown in FIG. 2C. The dome shape may be pulled off center due to the slit valve effect.

When ferrite boundaries are present, however, the standing wave maximum or peak spreads out in a direction perpendicular to the transversely oriented ferrite boundaries as compared to when no ferrites are present. As shown in FIG. 2B, the standing wave profile is substantially constant for most of the distance between the ferrite boundaries (x-direction). The maximum or peak of the standing wave is thus spread out for substantially the entire distance between the ferrite boundaries. Because the maximum or peak of the standing wave is substantially constant across substantially the entire distance between the ferrites, the plasma density may be substantially uniform across the electrode in the x-direction (showerhead in PECVD) as shown in FIG. 2D. It is believed that the RF current flowing to the bottom surface of the electrode from the sides that did not have ferrites thereon will form the standing wave in the y-direction, as shown in FIG. 2D. Thus, the RF current is flowing to the bottom surface of the electrode from only two sides. The ferrites have thus eliminated or substantially reduced the non-uniformity that would have been created by RF current flowing from the sides along which the ferrites are oriented (x-direction). By eliminating or reducing the RF current from the other two sides, the standing wave maximum is not compressed towards the center from the other two sides. In fact, little or no compression of the standing wave maximum towards the center occurs from the other two sides. Without the compression from the other two sides, the standing wave maximum or peak from the two sides having RF current flowing therefrom may be substantially uniformly spread across the width of the electrode. Hence, the standing wave profile shown in FIG. 2D has a maximum or peak spanning the substantial width of the electrode.

In comparing FIG. 2C to FIG. 2D, it can be seen that the standing wave of FIG. 2C will have a dome shape with the highest point that may be in the substantial center of the electrode or even shifted to a side due to the slit valve effect. However, when ferrites are present, the standing wave in the y-direction may span across substantially the entire width of the electrode perpendicular to the ferrite material (x-direction). In the embodiment shown in FIG. 2D, the ferrites are positioned in a direction perpendicular to the highest point of the standing wave (y-direction shown in FIG. 2A). Therefore, the standing wave can be extended in the direction perpendicular to the ferrite material such that the plasma may be substantially uniformly distributed in the direction perpendicular to the ferrites.

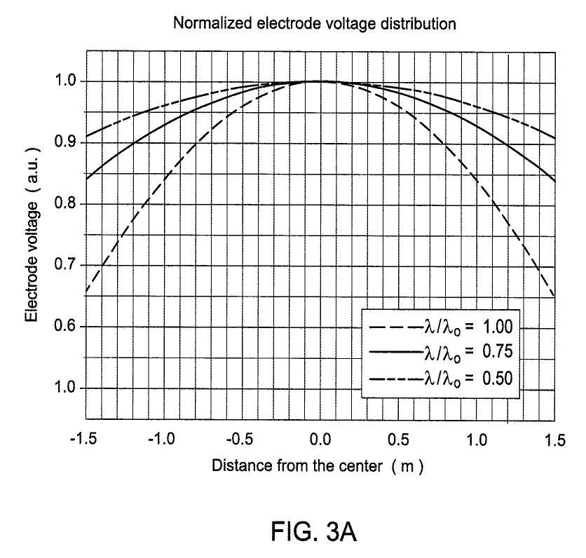

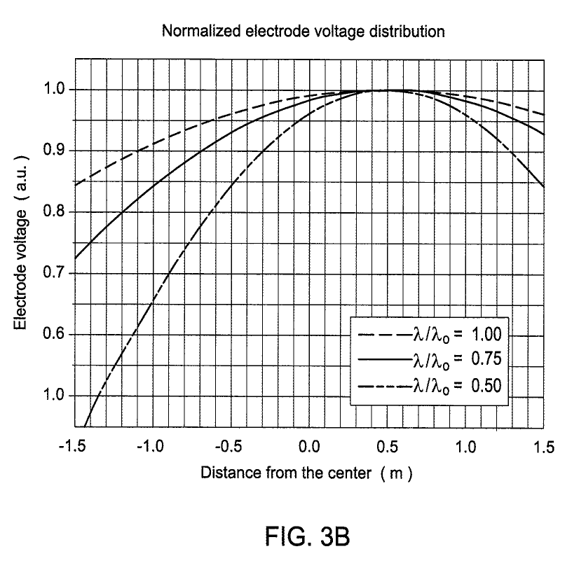

FIG. 3A shows a normalized electrode voltage distribution for a center fed RF feed. As can be seen from FIG. 3A, the electrode voltage is distributed substantially identical to both the left and right of center. FIG. 3B shows a normalized electrode voltage distribution for an RF feed displaced 0.5 meters from center. Here, the electrode voltage is distributed differently to the left and right of center. Thus, by shifting the RF feed, the standing wave can also be shifted.

FIG. 4 is a simplified schematic cross sectional view illustrating various locations in which ferrites 410 can be positioned in relation to a processing area 446 within a parallel plate apparatus 400. The ferrites 410 may be placed on the back surface of the electrode 404 (i.e., backing plate/showerhead illustrated in FIG. 1A), on the surface of the electrode 404 facing the substrate 408, adjacent the electrode 404, adjacent the susceptor 406, under the susceptor 406, or even on the walls 402. It is to be understood that if the ferrites 410 can be disposed at any location along the RF path from the bottom to the top of the chamber. When the ferrites 410 are behind the electrode 404, the ferrites 410 may be in an atmospheric environment. However, when the ferrites 410 are positioned under the susceptor 406, on the electrode 404 facing the substrate 408, or on the walls 402, they may need to be covered by a cover 412 to isolate them from the vacuum environment. The cover 412 can be used to prevent the ferrites 410 from contaminating the processing environment due to attack caused by the radicals in the plasma, oxidation, corrosion, or by sputtering caused energetic species in the plasma. In one embodiment, the cover 412 may comprise an insulating material. The benefits to having the ferrites 410 on the atmospheric side of the electrode 404 include easy access to the ferrites 410, not blocking or changing the flow of processing gas, and the need for less material because no cover is necessary. Additionally, the ferrites 410 may be between a backing plate and a showerhead in a PECVD system. The ferrites 410 may even be spaced from the electrode 404 for thermal purposes.

It is to be understood that the embodiments discussed herein may have utility in other chambers including those sold by other manufacturers. In certain embodiments uniform plasma in the apparatus and/or uniform process conditions in large area RF or VHF capacitive plasma reactors is achieved. The includes enhancing RF or VHF current uniformity in one direction (for example, the x-axis of a rectangular electrode), and power coupling scheme that moves the non-uniform standing wave field pattern in the other direction (for example, the y-axis of the rectangular electrode) during the deposition process. The ferrites may be used in any system that has an electrode, including systems without a showerhead such as a system with a top electrode and gas fed from sides of the chamber.

By utilizing ferrites strategically placed in a parallel plate reactor, better control of the RF or VHF current may occur. The ferrites may compensate for the standing wave effect and increase plasma uniformity. Due to an increased plasma uniformity, a more uniform and repeatable deposition may occur in the parallel plate reactor.

While the foregoing is directed to embodiments of the present invention, other and further embodiments of the invention may be devised without departing from the basic scope thereof, and the scope thereof is determined by the claims that follow.

1. An apparatus, comprising:
a chamber body having a slit valve opening through a first wall of the chamber body;
a gas distribution showerhead disposed in the chamber body above the slit valve opening;
a backing plate coupled to the chamber body and spaced from the gas distribution showerhead, the backing plate having a substantially rectangular shape, a first side facing the gas distribution showerhead, and a second side opposite the first side;
a power source coupled to the backing plate at a substantial center thereof; and
one or more first ferrite pieces extending along the second side of the backing plate.

2. The apparatus of claim 1, wherein the one or more first ferrite pieces extend substantially parallel to the slit valve opening.

3. The apparatus of claim 2, further comprising one or more second ferrite pieces extending along the second side of the backing plate and adjacent to a second wall opposite to the first wall.

4. The apparatus of claim 1, wherein the power source is an RF or VHF power source.

5. The apparatus of claim 1, wherein the one or more first ferrite pieces extend along an entire length of the slit valve opening.

6. The apparatus of claim 1, wherein the gas distribution showerhead has a plurality of gas passages extending therethrough and wherein the gas passages have hollow cathode cavities.

7. The apparatus of claim 6, wherein the one or more first ferrite pieces extend substantially parallel to the slit valve opening.

8. The apparatus of claim 7, further comprising one or more second ferrite pieces extending along the second side of the backing plate and adjacent to a second wall opposite to the first wall.

9. The apparatus of claim 8, wherein the power source is an RF or VHF power source.

10. The apparatus of claim 9, wherein the one or more first ferrite pieces extend along an entire length of the slit valve opening.

11. An apparatus, comprising:
a substantially rectangular shaped gas distribution showerhead;
a backing plate coupled to the gas distribution showerhead; and
one or more first ferrite blocks resting on the backing plate.

12. The apparatus of claim 11, wherein the one or more first ferrite blocks extend along at least a first edge of the backing plate.

13. The apparatus of claim 12, further comprising one or more second ferrite blocks resting on the backing plate.

14. The apparatus of claim 13, wherein the one or more second ferrite blocks extend along at least a second edge of the backing plate parallel to the first edge.

15. The apparatus of claim 11, further comprising a power source coupled to the backing plate on a surface upon which the one or more first ferrite blocks rest.

16. The apparatus of claim 15, wherein the power source is coupled to the backing plate at a single location.

17. A method, comprising:
applying an RF current to a backing plate of an apparatus, the apparatus having a gas distribution showerhead coupled to the backing plate and one or more ferrite blocks resting on an edge of the backing plate, the RF current applied such that at least a portion of a the RF current is suppressed in a direction perpendicular to the ferrite material;
introducing a processing gas through the gas distribution showerhead;
igniting the processing gas into a plasma; and
depositing material onto the substrate.

18. The method of claim 17, wherein a standing wave pattern of the RF current is substantially uniform in a direction perpendicular to the edge having the one or more ferrite blocks thereon.

19. The method of claim 17, wherein a standing wave pattern of the RF current is more uniform in a direction perpendicular to the edge having the one or more ferrite blocks as compared to an edge not having the one or more ferrite blocks.

20. The method of claim 17, wherein the RF current is applied in a substantial center of the backing plate.
